(19) United States
(12) Patent Application Publication
(10) Pub. No.: US 2007/0215941 A1
(43) Pub. Date: Sep. 20, 2007

(54) Semiconductor-On-Insulator Substrate Comprising A Buried Diamond-Like Carbon Layer And Method For Making Same

(75) Inventors: Simon Deleonibus, Claix (FR); Alain Deneuville, Saint-Egreve (FR)

Correspondence Address: OLIFF & BERRIDGE, PLC, P.O. BOX 19928, ALEXANDRIA, VA, 22320, US

(73) Assignees: Commissariat A L'Energie Atomique, Paris (FR); Universite Joseph Fourier, Grenoble (FR)

(21) Appl. No.: 10/594,222

(22) PCT Filed: Mar. 25, 2005
(86) PCT No.: PCT/FR05/00719

§ 371 Date: Nov. 8, 2006

(30) Foreign Application Priority Data
Mar. 25, 2004 (FR) 0403071

(51) Int. Cl. H01L 27/12

(52) U.S. Cl. 257/347; 438/455; 438/763; 257/E21.567

(57) ABSTRACT

The substrate successively comprises a base, a diamond-like carbon layer, a dielectric layer and a semi-conducting material layers which is designed to constitute microelectronic elements. A nucleation layer is preferably disposed between the base and the diamond-like carbon layer. The dielectric material is chosen such that the upper level of the valence band of the dielectric material is lower than the upper level of the valence band of the diamond-like carbon. The semi-conducting material is chosen such that the upper level of the valance band of the semi-conducting material is higher than the upper level of the valence band of the diamond-like carbon. The substrate can be achieved by successive depositions of by assembly of first and second stacks.

### BACKGROUND OF THE INVENTION

The invention relates to a semiconductor-on-insulator substrate successively comprising a base, a diamond-like carbon layer, a dielectric layer and a layer made of semi-conducting material designed to constitute microelectronic elements.

### STATE OF THE ART

Stray capacitances and thermal dissipation are the cause of great problems in circuits comprising several hundred million transistors, in particular in the power electronics field and in the field of high-speed integrated circuits. Typically, the transistors are made from silicon substrates or on semiconductor-on-insulator substrates comprising a semi-conducting base, a dielectric layer and a semi-conducting material layer designed to constitute microelectronic elements. The dielectric layer enables the electrostatic environment of transistors arranged on the dielectric layer to be improved compared with silicon substrates without a dielectric layer. However, the dielectric layer is typically made from materials which do not enable a sufficient thermal dissipation to be obtained, as illustrated in the document “SOI MOSFET Thermal Conductance and Its Geometry Dependence” by H. Nakayama et al. (2000 IEEE International SOI Conference, October 2000). Moreover, operation of the integrated circuits may be limited by short channel effects encountered in particular in transistors fabricated on semiconductor-on-insulator substrates.

The document WO02/43124-A describes fabrication of a semiconductor-on-insulator substrate comprising a thick layer, a diamond layer, a thin layer, for example made of sapphire, and a useful semi-conducting layer. The useful layer is for example made of GaN, AlN, AlGaN or GaInN. However, a stack made from these materials presents electronic properties which are not satisfactory.

The document DE4423067 proposes depositing layers having a high thermal conductivity, for example made of diamond or alumina, to obtain electrically insulating layers. The document DE4423067 describes a stack comprising a semi-conducting wafer, an insulating layer and a diamond layer.

The documents U.S. Pat. No. 5,863,324 and U.S. Pat. No. 5,743,957 describe fabrication of a diamond film on a platinum layer disposed on a base substrate.

### OBJECT OF THE INVENTION

It is an object of the invention to remedy these shortcomings and, in particular, to enable the operation of microelectronic elements to be improved, while reducing the size of the elements.

According to the invention, this object is achieved by the accompanying claims and, in particular, by the fact that the dielectric material is chosen such that the upper level of the valence band of the dielectric material is lower than the upper level of the valence band of the diamond-like carbon and that the semi-conducting material is chosen such that the upper level of the valence band of the semi-conducting material is higher than the upper level of the valence band of the diamond-like carbon.

It is a further object of the invention to provide a method for producing a substrate according to the invention comprising preparation of a first stack by:
deposition of the diamond-like carbon layer on the base,
and deposition of the dielectric layer on the diamond-like carbon layer.

### BRIEF DESCRIPTION OF THE DRAWINGS

Other advantages and features will become more clearly apparent from the following description of particular embodiments of the invention given as non-restrictive examples only and represented in the accompanying drawings, in which:

FIG. 1 represents a particular embodiment of a substrate according to the invention.

FIGS. 2 and 3 illustrate two microelectronic devices produced from a substrate according to FIG. 1.

FIGS. 4 and 5 respectively represent assembly and etching steps of a particular embodiment of a method for making a substrate according to the invention.

FIGS. 6 and 7 respectively represent assembly and dissociation steps of a particular embodiment of a method for making a substrate according to the invention.

FIG. 8 represents the upper levels of the valence bands of the diamond-like carbon, of the dielectric material and of the semi-conducting material of a particular embodiment of a substrate according to the invention.

### DESCRIPTION OF PARTICULAR EMBODIMENTS

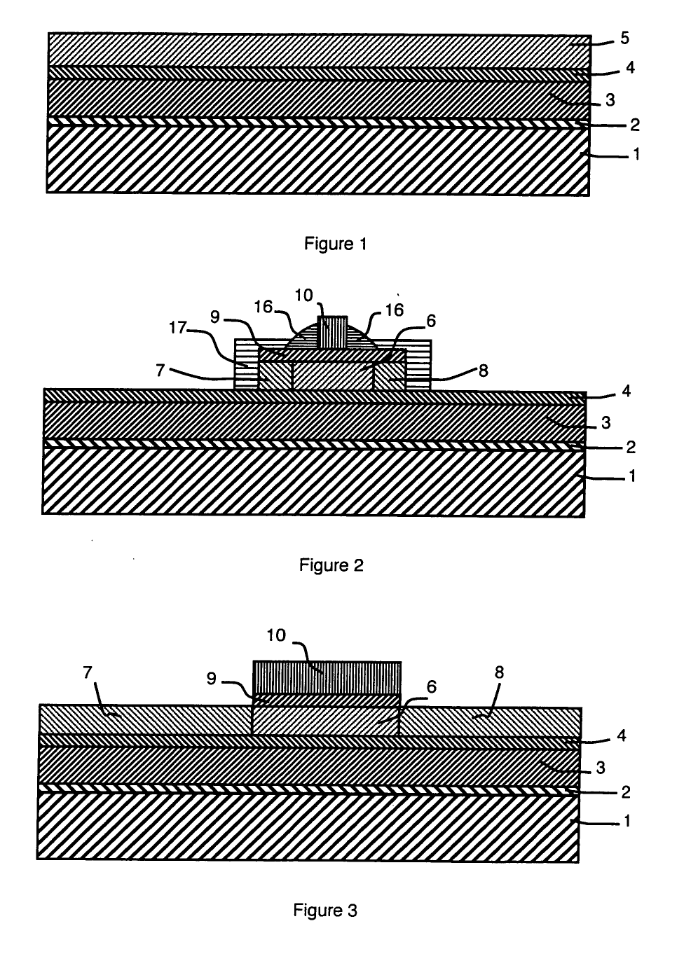

In FIG. 1, the semiconductor-on-insulator substrate successively comprises a base 1, preferably a semi-conducting base, typically made of silicon, a nucleation layer 2, which is not compulsory, a diamond-like carbon layer 3, a dielectric layer 4, preferably with a high dielectric constant, and a layer of semi-conducting material 5 designed to constitute microelectronic elements. The dielectric constant of diamond-like carbon is 5.7 and its thermal conductivity is comprised between 1500 and 2000 W/m/K, depending on the deposition method used, whereas the dielectric constant of silicon is 11.9 and its thermal conductivity is 140 W/m/K, at ambient temperature. The thermal conductivity of diamond-like carbon therefore being about ten times greater than that of silicon, the buried diamond-like carbon layer 3 enables a good heat removal to be obtained, while minimizing the stray capacitances and limiting the short channel effects. The dielectric constant of diamond-like carbon in fact enables an adaptation to be made to the dielectric constants of the different layers constituting the substrate.

As represented in FIG. 8, the dielectric material 4 is chosen such that the upper level Edi of the valence band of the dielectric material 4 is lower than the upper level Ecd of the valence band of the diamond-like carbon 3 (Edi<Ecd). The semi-conducting 5 material is chosen (FIG. 8) such that the upper level Esc of the valence band of the semi-conducting material 5 is higher than the upper level Ecd of the valence band of the diamond-like carbon 3 (Esc>Ecd).

The dielectric layer 4 is for example made of preferably monocrystalline alumina (Edi=−8.1 eV), hafnium oxide Hf02 (Edi=−7.67 eV) or zirconium oxide ZrO2 (Edi=−7.57 eV). Thus, the upper level Edi of the valence band of the dielectric layer 4 is lower than the upper level Ecd of the valence band of diamond-like carbon 3 which is −5.47 eV. The semi-conducting material layer 5 is for example made of silicon Si (Esc=−5.17 eV), germanium Ge (Esc=−4.79 eV) or indium antimonide InSb (Esc=−4.75 eV). The upper level Esc of the valence band of the semi-conducting material layer 5 is thus higher than the upper level Ecd of the valence band of the diamond-like carbon 3 (Ecd=−5.47 eV). The choice of these semi-conducting materials for the semiconductor-on-insulator substrate enables the operation of microelectronic elements to be improved. Semi-conducting materials, unlike the invention, having an upper level Esc of the valence band that is lower than that of diamond (for example GaN: Esc=−7.3 eV) would in fact present the disadvantage that the holes of the layer semi-conducting 5, which are positive charge carriers, move towards the diamond 3, impairing the operation of the microelectronic elements. The dielectric layer 4 forms a potential barrier further preventing migration of the holes of the semi-conducting material layer 5 towards the diamond-like carbon layer 3, provided that the upper level Edi of the valence band of the dielectric material 4 is lower than the upper level Ecd of the valence band of the diamond-like carbon 3.

In FIG. 2, the semi-conducting material layer 5 is etched to form a transistor channel 6 comprising a source 7, a drain 8, a gate insulator 9, a gate electrode 10, lateral insulators 16 and metallic contact elements 17 for contact connection on the source 7 and drain 8. It is possible, after the material 5 has been etched, to deposit another semi-conducting material on the zones of the substrate where the semi-conducting material 5 was removed, to achieve transistors having a channel of another type.

As an alternative embodiment, the source 7 and drain 8 can for example be obtained, in known manner, by ion implantation in the semi-conducting material 5, as represented in FIG. 3.

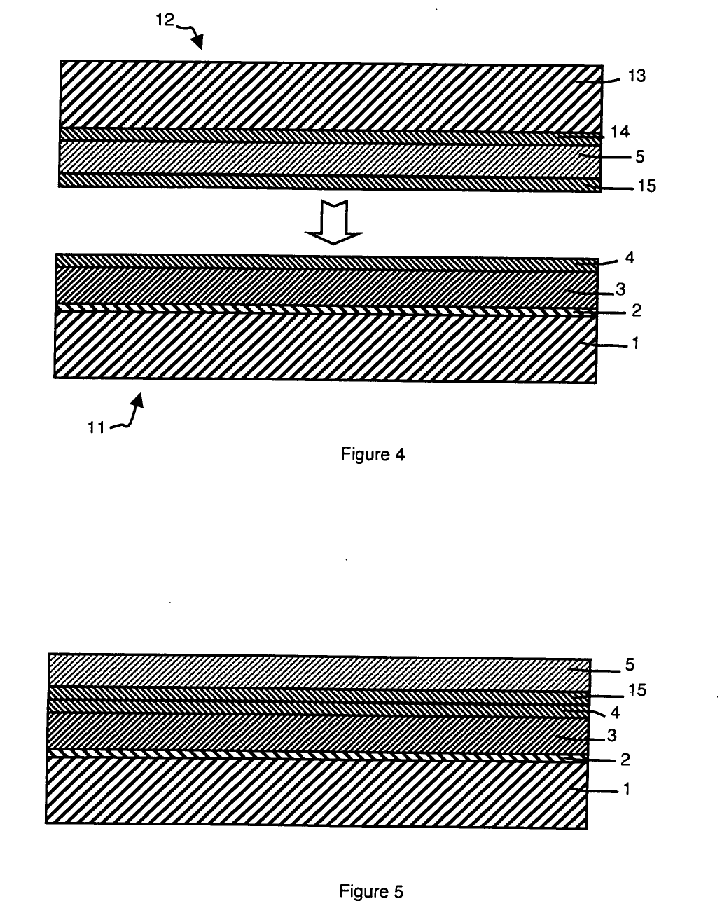

A method for producing a substrate according to the invention preferably comprises preparation of a first stack 11, represented in FIG. 4, by deposition of the nucleation layer 2, the diamond-like carbon layer 3 and the dielectric layer 4 on the base 1. The diamond-like carbon layer 3 can be deposited directly on the base 1. However the presence of the nucleation layer 2 facilitates deposition of the diamond-like carbon layer 3 on the base 1. The nucleation layer 2 is for example deposited by epitaxy. In a first embodiment, the nucleation layer 2 is made of metallic material, for example nickel, iridium or platinum, to remove heat as best as possible. In a second particular embodiment, the nucleation layer 2 is made of preferably monocrystalline alumina (Al₂O₃), which presents the advantage of having a crystalline structure suitable for deposition of the diamond-like carbon. However, the thickness of the alumina nucleation layer 2 is preferably minimized to reduce the thermal resistance of the nucleation layer 2. The nucleation layer 2 can also be made of strontium titanate (SrTiO₃).

The diamond-like carbon layer 3 is preferably deposited by epitaxy on the nucleation layer 2. Then the dielectric layer 4 is made to grow, preferably by epitaxy of a material with a high dielectric constant, for example SrTi0₃, Al₂O₃ or HfO₂, designed to form the buried insulator of the semiconductor-on-insulator substrate. The dielectric layer 4 can also be deposited by chemical gas deposition or by plasma enhanced deposition. In this case, the diamond-like carbon 3 is preferably planarized before this deposition is performed. The dielectric layer 4 is preferably made of alumina, preferably monocrystalline alumina. This enables a very good compromise to be obtained between the stray capacitances and the heat removal, the dielectric constant of alumina being 10 and the thermal conductivity being comprised between 25 and 43 W/m/K, depending on the deposition method used. Monocrystalline alumina notably has a thermal conductivity of 43 W/m/K. The heat produced in the microelectronic elements disposed at the surface of the substrate is thus removed and the stray capacitances of the transistor environment are minimized by the stack formed by the nucleation layer 2, the diamond-like carbon layer 3 and the dielectric layer 4.

In a first particular embodiment of a method for making the substrate, the semi-conducting material 5 designed to constitute microelectronic elements is then deposited on the dielectric layer 4, as represented in FIG. 1. The material 5 is preferably deposited by epitaxy. Microelectronic elements are then produced, in known manner, from the semi-conducting material 5, as represented in FIGS. 2 and 3.

In a second particular embodiment of a method for making the substrate, represented in FIG. 4, a second stack 12 of a first additional dielectric layer 14, of the semi-conducting material 5 designed to constitute microelectronic elements and of a second additional dielectric layer 15, is prepared, for example by successive depositions on an additional base 13. The first 14 and second 15 additional dielectric layers can be achieved by epitaxy of a high dielectric constant material. The semi-conducting material 5 can be produced for example by epitaxy. The first 11 and second 12 stacks are then assembled by molecular bonding of the second additional dielectric layer 15 and of the dielectric layer 4. In practice, one of the stacks, the second stack 12 in FIG. 4, is then turned and placed on the other stack, under suitable temperature and pressure conditions. Then the additional base 13 is removed by etching. As the first additional dielectric layer 14 has undergone etching of the additional base 13, it is preferably removed at the end of the process, as represented in FIG. 5.

The dielectric layer of the substrate thus obtained is then formed by superposition of two dielectric layers, more particularly by superposition of the second additional dielectric layer 15 and of the dielectric layer 4, as represented in FIG. 5.

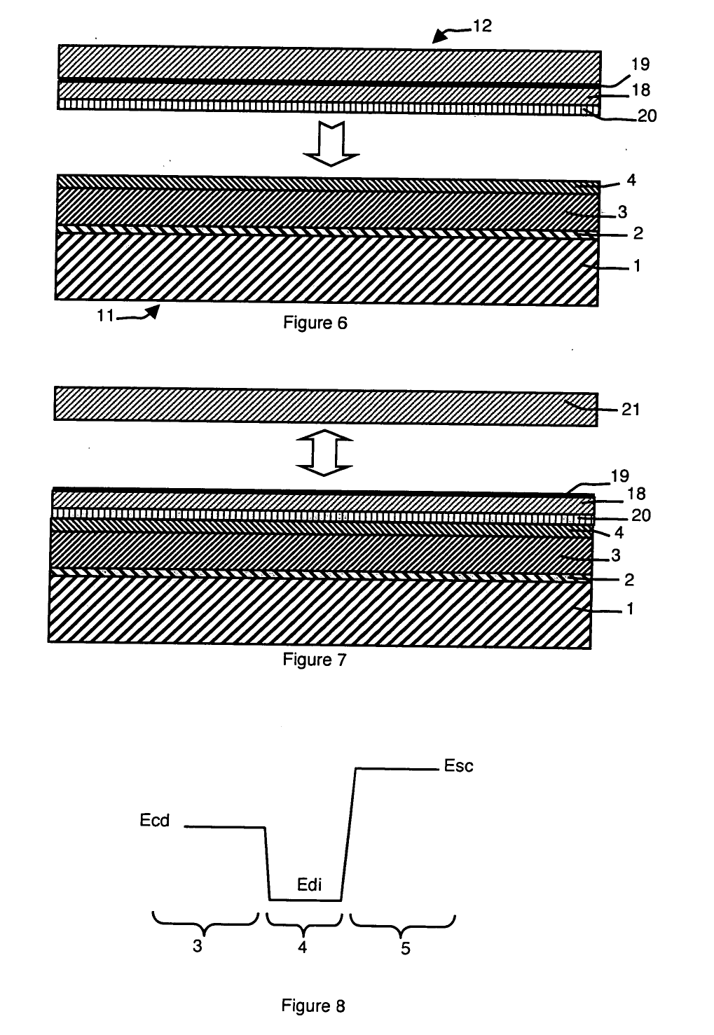

In a third particular embodiment of a method for making the substrate, illustrated in FIGS. 6 and 7, the second stack 12 is formed by an additional semi-conducting substrate, which may be bulk or not, comprising at the surface thereof a thin film 18 of the semi-conducting material 5 designed to constitute microelectronic elements. This additional substrate comprises a buried zone 19 fragilized by implantation, delineating the thin film 18 of the semi-conducting material 5 in this additional substrate. The thin film 18 can be oxidized to form a thermal oxide layer 20, at the surface thereof, represented in FIG. 6.

As represented in FIG. 6, the first 11 and second 12 stacks are assembled by molecular bonding of the dielectric layer 4 and of the thin film 18 comprising the layer 20. The second stack 12 is then dissociated (FIG. 7) at the level of the fragilized buried zone 19, by thermal and/or mechanical treatment, so as to obtain a residue 21 of the second stack 12.

The invention is not limited to the embodiments represented. In particular, as indicated, the nucleation layer 2 is not compulsory. For certain applications, the base 1 can be polarized and deposition of diamond be fostered by acceleration from a carbonaceous gas at high temperature. The deposit obtained is strongly oriented and remains compatible with a large number of applications, in particular if the diamond layer has a thermal function only.

1. Semiconductor-on-insulator substrate successively comprising a base, a diamond-like carbon layer, a layer made of dielectric material and a layer made of semi-conducting material designed to constitute microelectronic elements, the dielectric material being chosen such that the upper level of the valence band of the dielectric material is lower than the upper level of the valence band of the diamond-like carbon and the semi-conducting material being chosen such that the upper level of the valence band of the semi-conducting material is higher than the upper level of the valence band of the diamond-like carbon, substrate characterized in that it comprises an alumina nucleation layer disposed between the base and the diamond-like carbon layer.

2. Substrate according to claim 1, wherein the semi-conducting material is chosen from silicon, germanium and indium antimonide.

3. Substrate according to claim 1, wherein the dielectric material is chosen from alumina, hafnium oxide and zirconium oxide.

4. Substrate according to claim 3, wherein the dielectric material layer is made of monocrystalline alumina.

5. Substrate according to claim 1, wherein the nucleation layer is made of monocrystalline alumina.

6. Substrate according to claim 1, wherein the dielectric material layer is formed by superposition of two dielectric layers.

7. Method for making a substrate according to claim 1, comprising preparation of a first stack by:
deposition of the diamond-like carbon layer on the base, and
deposition of the dielectric material layer on the diamond-like carbon layer.

8. Method according to claim 7, comprising deposition of the nucleation layer on the base, before deposition of the diamond-like carbon layer.

9. Method according to claim 7, comprising deposition of the semi-conducting material designed to constitute microelectronic elements, after deposition of the dielectric material layer.

10. Method according to claim 7, comprising preparation of a second stack by:
deposition of a first additional dielectric layer on an additional base,
deposition of the semi-conducting material designed to constitute microelectronic elements, on the first additional dielectric layer, and
deposition of a second additional dielectric layer on the semi-conducting material, and
after preparation of the first and second stacks, assembly of the first and second stacks by molecular bonding of the second additional dielectric layer and of the dielectric material layer, the additional base then being removed by etching.

11. Method according to claim 10, comprising removal of the first additional dielectric layer.

12. Method according to claim 7, wherein, a second stack being formed by an additional substrate comprising a thin film of the semi-conducting material designed to constitute microelectronic elements, the thin film being delineated by a buried zone fragilized by implantation, the first and second stacks are assembled by molecular bonding of the thin film and of the dielectric material layer, the second stack being dissociated, after bonding, at the level of the fragilized buried zone.

13. Method according to claim 12, comprising thermal oxidation of the thin film, before assembly, so as to form a thermal oxide layer.
